(19) United States
(12) Patent Application Publication
(10) Pub. No.: US 2026/0093873 A1
(43) Pub. Date: Apr. 2, 2026

(54) CONVOLUTIONAL NEURAL NETWORKS FOR EXTRACTING NON-LINEAR COMPACT MODELS

(71) Applicant: Qorvo US, Inc., Greensboro, NC (US)

(72) Inventors: Sourabh Khandelwal, Plano, TX (US); Yan Li, Claremont, CA (US); Kaijie Yu, La Verne, CA (US)

(21) Appl. No.: 19/298,391

(22) Filed: Aug. 13, 2025

Related U.S. Application Data
(60) Provisional application No. 63/700,997, filed on Sep. 30, 2024.

(51) Int. Cl. G06F 30/27; G06N 3/0464

(52) U.S. Cl. CPC G06F 30/27; G06N 3/0464

(57) ABSTRACT

A method for extracting parameters of semiconductor devices is provided. The method involves processing input data representing electrical characteristics of the semiconductor device through one or more convolution layers of a CNN to detect local patterns and extract features, down-sampling the processed data through one or more pooling layers to reduce spatial dimensions while retaining important features, passing the output of the pooling layers through one or more fully connected layers to perform high-level reasoning and decision-making based on extracted features, and generating predictions for parameters of the semiconductor device using an output layer of the CNN. The method includes reshaping input data to generate a shaped data set with array dimensions based on the number of input steps generated for the semiconductor device. The method also scales the shaped data set according to the range of values in the semiconductor device's measured current or other relevant measured electrical quantities.

### RELATED APPLICATIONS

This application claims the benefit of provisional patent application Ser. No. 63/700,997, filed Sep. 30, 2024, the disclosure of which is hereby incorporated herein by reference in its entirety.

### FIELD OF THE DISCLOSURE

The present disclosure relates to methods for enhancing the performance of convolutional neural networks (CNNs) in the parameter extraction of non-linear compact models describing the electrical behavior of semiconductor devices.

### BACKGROUND

Non-linear compact models describe the non-linear electrical behavior of semiconductor devices. These models contain many parameters to describe the device behavior. These parameters need to be extracted from measurements, and extraction is a complex and time-consuming task.

Artificial intelligence techniques are being explored to perform the task of parameter extraction. One of the artificial intelligence network architectures which looks promising for this application is convolutional neural networks or CNNs. A CNN is a type of deep learning artificial intelligence model designed primarily for analyzing visual imagery. The CNN uses a series of filters to automatically and adaptively learn spatial hierarchies of features from images, making it particularly effective in image recognition and classification tasks. CNNs process data by convolving filters over local regions of an input volume, such as an image, to extract increasingly abstract features at each layer. CNNs have been applied in applications such as image classification and image analysis. CNNs operate with images as inputs and learn patterns from these. The images are typically fed into CNNs in the form of a certain number of pixels in an image with a value of each pixel assigned based on grey scale.

Disclosed is a method of shaping the inputs to the CNN and assigning values to pixels that yields higher accuracy for the CNN learning and training process when deployed for parameter extraction of non-linear compact models.

### SUMMARY

A method of extracting non-linear compact model parameters for electronic devices using a convolutional neural network (CNN) is provided. The CNN includes input, convolution, pooling, fully connected, and output layers. The input layer receives data representing electrical characteristics of an electronic device. The convolution layers detect local patterns in the data and extract features therefrom. The pooling layers down-sample the processed data to reduce spatial dimensions while retaining important features. The fully connected layers perform high-level reasoning and decision-making based on extracted features. The output layer generates predictions for non-linear compact model parameters of the electronic device.

The CNN architecture includes two or more convolutional kernels with the same padding, and one or more pooling layers, such as maximum pooling layers, to help reduce variations in the input data that may include out of range values, and thus, reduce the possibility of predicting out of range values for each parameter. The CNN method improves accuracy in extracting non-linear compact model parameters compared to conventional methods.

The electronic devices can include transistors, diodes, or other types of electronic components. The method can be applied to various semiconductor technologies, such as silicon, gallium arsenide, or gallium nitride, with varying numbers of parameters. The pixel-based approach for applying CNNs in electrical behavior modeling has advantages that substantially improve the semiconductor industry by improving parameter extraction and reducing reliance on expert intervention or time-consuming processes.

The method includes data shaping based on transistor input voltage ranges, scaling and value assignment based on electronic device current behavior, and faster training times compared to conventional CNN methods, resulting in improved accuracy for all parameters tested. The method can be implemented using software or hardware components, such as a memory storing input data representing electrical characteristics of an electronic device and a processor configured to execute instructions stored in the memory.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is a schematic diagram depicting the architectural flow of a convolutional neural network (CNN) used for processing and classifying input data in accordance with the present disclosure.

FIG. 2 is a schematic diagram depicting the architectural flow of an enhanced CNN used for processing and classifying input data in accordance with the present disclosure.

FIG. 3 is a grayscale image that in accordance with the present disclosure is representation of input image used to predict characteristics for an electronic device.

FIG. 4 is a procedural chart for a method in accordance with the present disclosure.

FIG. 5 is a plot showing drain current (Id) versus gate voltage for a plurality of drain voltage values.

FIG. 6 is a schematic diagram of a generalized representation of a computer system that may be employed for executing method steps in accordance with the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

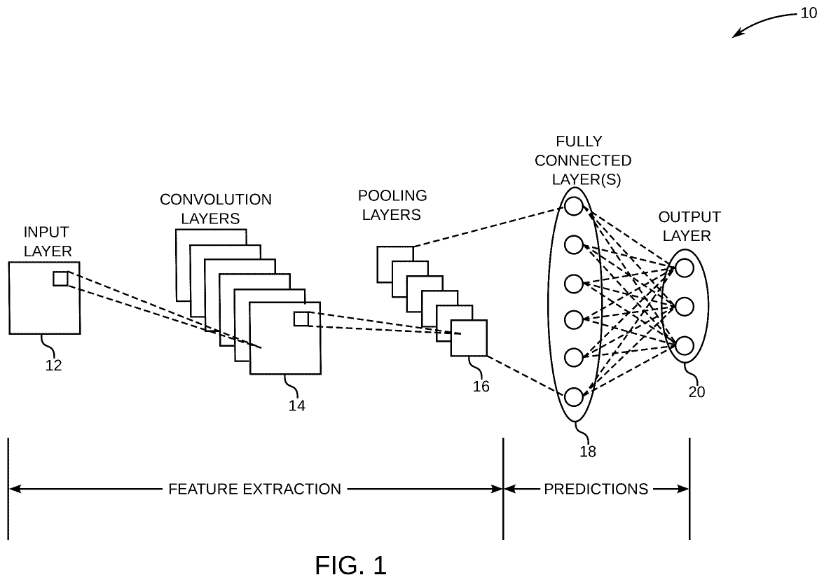

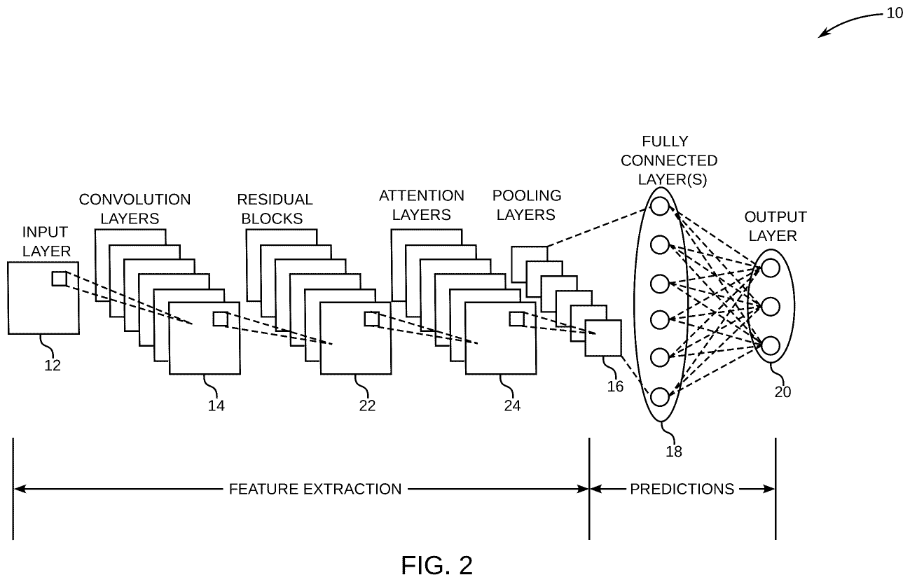

FIG. 1 is a schematic diagram depicting the architectural flow of a convolutional neural network (CNN) 10 used for processing input data, typically an image. An input layer 12 is configured to receive an input image which typically represents a grayscale or RGB image. FIG. 2 is a grayscale image that in accordance with the present disclosure is representation of input image used to predict characteristics for an electronic device. The input image is subjected to feature extraction by subsequent layers in the CNN 10. Some of the subsequent layers are convolution layers 14. Each of the convolution layers 14 applies a set of filters to the input image or previous layer's output to detect local patterns. Traditionally, the local patterns may be edges, textures, or other image features. In contrast, the local patterns detected by the CNN 10 in accordance with the present disclosure are not image features but are instead electrical characteristics of electronic devices. These filters produce multiple feature maps, as shown by the stacked squares representing processed feature maps. The filters scan the image using a sliding window technique, convolving small regions (receptive fields) and aggregating information, enhancing the model's capacity to detect complex patterns.

Following the convolution layers 14 are pooling layers 16, typically used for down-sampling the feature maps. The pooling operation reduces the spatial dimensions (width and height) of the input while retaining the most important features. In FIG. 1, this is depicted as a reduction in the size of the output feature maps, represented by smaller stacked squares. A maximum pooling layer within the pooling layers 16 is a type of pooling layer that reduces the spatial dimensions of the input by taking the maximum value within a specified window. This helps to control overfitting and improve the generalization ability of the CNN 10 and help preserve the most relevant features for the predictive task. The maximum pooling layer is used to control the predictions of the CNN 10. In accordance with the present disclosure there are some physical ranges for semiconductor device parameters to be predicted, and it is undesirable for the CNN to predict values outside of the physical ranges.

The Max pooling layer is employed to help reduce variations in the input data that may include out of range values, and thus, reduce the possibility of predicting out of range values for each parameter.

After the pooling layers 16, the output is passed through one or more fully connected layers 18, which are depicted by a series of nodes connected in a dense network. The one or more fully connected layers 18 perform high-level reasoning and decision-making, based on the features extracted by the convolution layers 14 and the pooling layers 16. Nodes of the one or more fully connected layers 18 are represented by circles in FIG. 1. Each node in one layer of the one or more fully connected layers 18 is connected to every node in the subsequent layer of the one or more fully connected layers 18. The connection between the nodes is depicted by dashed lines between the nodes.

The one or more fully connected layers 18 culminate in an output layer 20, which may include one or more nodes depending on the nature of the classification task. The output layer is configured to generate predictions, with each node corresponding to a possible regression value.

One of the main requirements for training of CNNs for extraction of parameters of non-linear compact models is to achieve high accuracy. The method according to the present disclosure provides an improvement in accuracy that was observed for multiple parameters for the application on which the disclosed technique was applied. The disclosed technique has been applied when using CNNs for an Advanced Simulation Program with Integrated Circuit Emphasis (SPICE) Model for high electron mobility transistors (ASM-HEMT) non-linear compact model parameter extraction. For modeling the current-voltage (I-V) behavior of gallium nitride (GaN) transistors, the ASM-HEMT model has 15 parameters. When the disclosed method is used with CNNs, better accuracy is achieved for all 15 parameters compared with the accuracy achieved with a conventional style of input shaping and value assignments. Moreover, as shown in FIG. 2, embodiments of the present disclosure may add residual blocks 22 to form a residual neural network that is a type of deep learning architecture. Also, in these embodiments, attention layers 24 may be added to enhance the CNN's focus on more relevant members of the input data. Both of these enhancements allow for training deeper neural networks to have increased accuracy.

In further regard, the attention layers 24 are designed to focus the attention of the CNN 10 on more relevant parts of the input data. This mechanism allows the CNN 10 to prioritize important features over less desired ones, enhancing the overall performance of the CNN 10. The core function of the attention layers 24 is to compute a weighted sum of the input features, where the weights indicate the importance of each feature. This process can be achieved through various mechanisms, such as self-attention as seen in Transformer models or additive/multiplicative attention layers. By incorporating the attention layers 24, the CNN 10 can better capture long-range dependencies and ignore irrelevant parts of the input data. This function is particularly beneficial in tasks where certain features are more critical than others, leading to improved performance.

The residual blocks 22 comprising skip connections play a crucial role in mitigating the vanishing gradient problem, which is prevalent in very deep neural networks. This issue can impede effective training of such networks. By employing the residual blocks 22, the CNN 10 learns the residual function with reference to the inputs rather than directly mapping from input to output. The output of each of the residual blocks 22 is then calculated as the sum of the original input and the learned residual. This technique enhances training stability and allows for the construction of deeper networks. Additionally, by preserving important features from previous layers, the residual blocks 22 may potentially lead to better overall performance of the CNN 10.

Certain embodiments according to the present disclosure may include the following:
Data shaping: In the conventional method, the CNN operates by taking in images which consist of pixels. Each pixel has a numeric value based on gray scale. Typically, images can be 128×128 pixels with a numerical unscaled value for each pixel varying between 0 to 255. In the disclosed method the data are reshaped based on the transistor input voltage ranges rather than by 128×128 pixels or any such arbitrary size. In the latter case the transistor has two input voltages which are gate voltage (Vg) and drain voltage (Vd). Data according to the present disclosure have 41 Vd conditions and 31 Vg conditions. So, the data reshaped as 31×41.
Scaling and value assignment: After shaping the data, scaling is applied based on the GaN transistor current behavior as opposed to the conventional method of assigning values to the pixels used in the CNN. In the conventional method, pixel values are scaled by 255. However, in the disclosed method data are scaled according to the range seen in the GaN transistor drain current data. After performing the foregoing operations, the data is fed into the CNN 10.

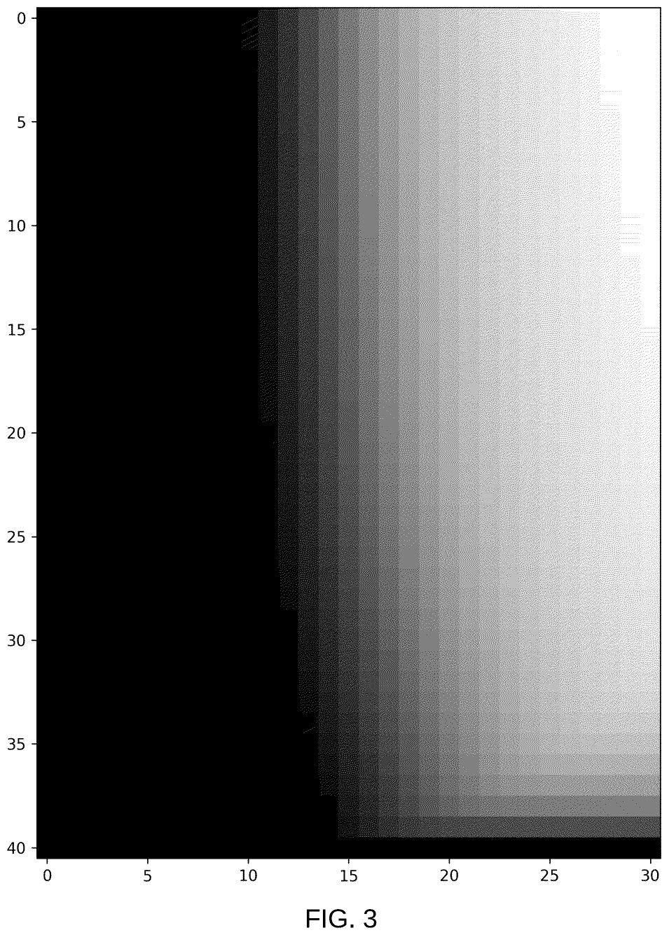

FIG. 3 is a grayscale image that in accordance with the present disclosure is a representation of an input image used to predict characteristics for an electronic device.

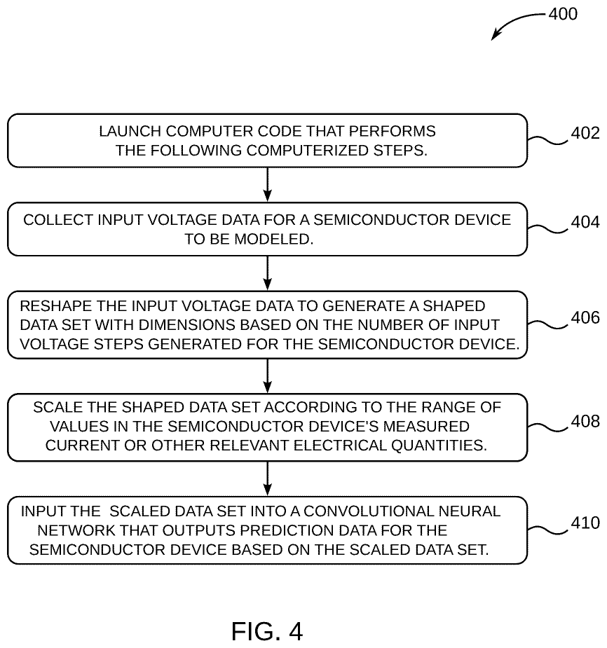

The present disclosure provides a method that provides faster training times compared to conventional CNN methods. Referring to FIG. 4, the method employs a computer executed procedure 400 that prepares data for the CNN 10 that is configured to output predictions of parameters for a semiconductor device. The method performs the following computerized steps by launching computer code (step 402). Next, input voltage data is collected for a semiconductor device to be modeled (step 404). The input voltage data is then reshaped to generate a shaped data set with array dimensions based on the number of input voltage steps generated for the semiconductor device (step 406). The shaped data set is scaled according to the range of values in the semiconductor device's measured current or other relevant measured electrical quantities (step 408). Finally, the scaled data set is input into the CNN 10 that outputs characterization data for the semiconductor device based on the scaled data set (step 410).

While convolutional neural networks (CNNs) can be generally applied to extraction of non-linear compact model parameters, in the disclosed application, CNN is deployed for extraction of model parameters of the Advanced SPICE Model for high electron mobility transistors (ASM-HEMT) non-linear compact model. A total of 15 parameters of this model related to the current-voltage (I-V) behavior of the transistor are extracted. Some 150,000 I-V curves of GaN transistor behavior are used as the training, validation, and test data for the CNN.

In an exemplary embodiment, data was collected for the following fifteen parameters of a HEMT:
VOFF—Pinch-off voltage or threshold voltage
VDSCALE—Drain induced barrier lowering saturation effect parameter.
ETA0—Drain induced barrier lowering effect parameter.
NFACTOR—Sub-threshold slope parameter.
CDSCD—Sub-threshold slope degradation with drain voltage parameter.
LAMBDA—Channel length modulation factor
U0—Carrier mobility.
MEXPACCD-Non-linear access region resistance parameter for drain-side access region.
MEXPACCS-Non-linear access region resistance parameter for source-side access region.
NS0ACCD—2-DEG charge density at the drain side access region
NS0ACCS—2-DEG charge density at the drain side access region U0ACCD—Carrier mobility in the drain-side access region.
U0ACCS—Carrier mobility in the drain-side access region
VSATACCS—Saturation velocity in the access regions
VSAT—Carrier saturation velocity in the channel region.

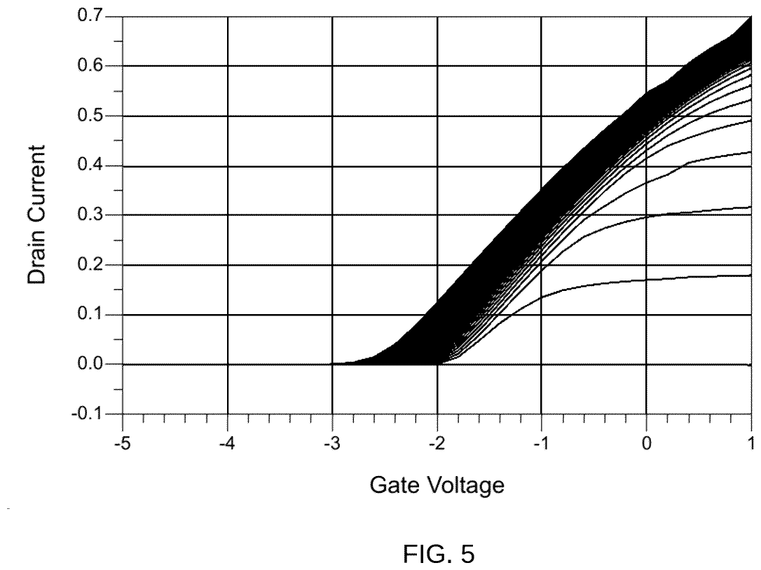

The I-V data set has the following properties. The input gate voltage (Vg) ranges from −5 V to 0 V with 0.2-V steps, making a total of 31 values. The input drain voltage (Vd) ranges from 0 V to 20 V with 0.2-V steps, making a total of 41 values. Therefore, in this exemplary embodiment, one I-V curve has 31×41=1271 points. The data set contains 150,000 such I-V curves, making a total of 190 million data points. One such I-V curve is shown in FIG. 5, in which Vg values are on the x-axis, current (Id) values are on the y-axis, and there are 41 curves, one for each Vd.

In the conventional method, the foregoing image is used in the form of an arrangement of pixels with each pixel assigned a value as per grey scale value. Typically, an image is shaped in the form of 128×128 pixels. In the disclosed method, the data are shaped considering the input conditions in the data, that is, Vg and Vd conditions. Thus, data are shaped in the form of 31×41 pixels.

The disclosed method also differs from the conventional method in values assigned to each point. In the conventional method, each pixel is assigned a value as per the grey scale. In the disclosed method, each point is scaled as per the drain-current value with the following rule applied for scaling:

$${I}_{scale} = ( {I}_{value} - {I}_{min} ) / ( {I}_{max} - {I}_{min} ) .$$

Using the foregoing scaling and shaping of the data, the input to the CNN input is transformed in a very different manner compared with the conventional method.

When a CNN of the same complexity is trained with the conventional method and with the disclosed method, better accuracy was obtained across all 15 parameters using the disclosed method. The CNN architecture used has two convolutional kernels with a padding of 1. A maximum pooling layer also was used in the CNN architecture.

A comparison of error in the extracted parameters for conventional and the disclosed method is shown in Table 1. An improvement in accuracy, that is, lower error for both training and test errors, can be seen for all 15 parameters when the disclosed method is used. The reported errors in the table below are median absolute percentage errors (%).

TABLE 1

| Parameter | Conventional Method: | Disclosed Method: |
|---|---|---|
| Name | Training Error/Test Error | Training Error/Test Error |
| VOFF | 0.40/0.43 | 0.38/0.39 |
| VDSCALE | 2.54/2.77 | 1.45/1.48 |
| ETA0 | 2.14/2.27 | 1.19/1.21 |
| NFACTOR | 7.29/8.26 | 4.43/4.42 |
| CDSCD | 9.71/11.05 | 3.85/3.89 |
| LAMBDA | 23.45/24.55 | 13.35/13.36 |
| U0 | 8.72/9.02 | 4.03/4.08 |
| MEXPACCD | 9.80/10.67 | 6.84/6.88 |
| MEXPACCS | 8.67/9.26 | 6.55/6.66 |
| NS0ACCD | 7.59/8.26 | 7.13/7.18 |
| NS0ACCS | 7.34/8.03 | 7.19/7.31 |
| U0ACCD | 12.54/13.23 | 11.80/11.80 |
| U0ACCS | 14.25/14.87 | 13.99/14.06 |
| VSATACCS | 8.99/9.62 | 7.61/7.76 |
| VSAT | 8.12/8.57 | 4.87/4.86 |

Table 1 demonstrates the improvement achieved with the disclosed method.

As illustrated by Table 1, the present disclosure demonstrates improved parameter extraction compared to conventional CNN methods that use actual images of plots of electrical characteristic data for electrical behavior modeling in semiconductor devices. By treating each sample as if it were a pixel, the presently disclosed method offers better results than other approaches.

Although the described implementation was tested on gallium nitride transistor technology with 15 parameters, the disclosed method can be extended to other electrical models, diodes, and semiconductor technologies, such as silicon or gallium arsenide, with varying numbers of parameters. Moreover, the present disclosure's unique pixel-based approach for applying CNNs in electrical behavior modeling has advantages that substantially improve the semiconductor industry by improving parameter extraction and reducing reliance on expert intervention or time-consuming processes.

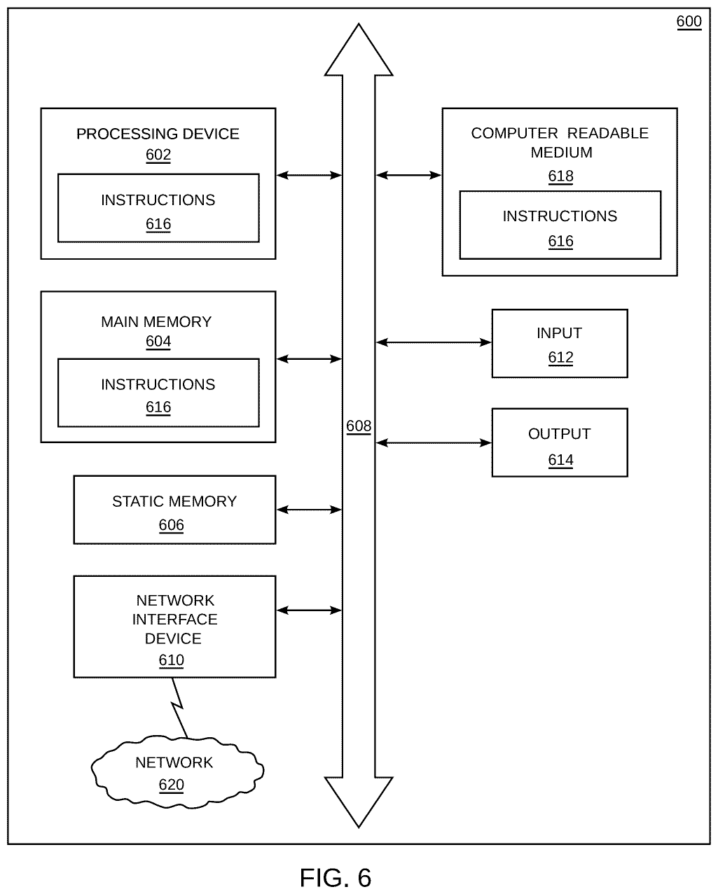

FIG. 6 is a schematic diagram of a generalized representation of a computer system 600 that may be employed for executing method steps disclosed herein, according to one embodiment. In this regard, the computer system 600 is adapted to execute instructions from a computer-readable medium to perform these and/or any of the functions or processing described herein.

In this regard, the computer system 600 in FIG. 6 may include a set of instructions that may be executed to program and configure programmable digital signal processing circuits for supporting scaling of supported communications services. The computer system 600 may be connected (e.g., networked) to other machines in a LAN, an intranet, an extranet, or the Internet. While only a single device is illustrated, the term “device” shall also be taken to include any collection of devices that individually or jointly execute a set (or multiple sets) of instructions to perform any one or more of the methodologies discussed herein. The computer system 600 may be a circuit or circuits included in an electronic board card, such as a printed circuit board (PCB), a server, a personal computer, a desktop computer, a laptop computer, a personal digital assistant (PDA), a computing pad, a mobile device, or any other device, and may represent, for example, a server or a user's computer.

The computer system 600 in this embodiment includes a processing device or processor 602, a main memory 604 (e.g., read-only memory (ROM), flash memory, dynamic random-access memory (DRAM), such as synchronous DRAM (SDRAM), etc.), and a static memory 606 (e.g., flash memory and static random-access memory (SRAM)), which may communicate with each other via a data bus 608. Alternatively, the processing device 602 may be connected to the main memory 604 and/or the static memory 606 directly or via some other connectivity means. The processing device 602 may be a controller, and the main memory 604 or static memory 606 may be any type of memory.

The processing device 602 represents one or more general-purpose processing devices, such as a microprocessor, central processing unit, or the like. More particularly, the processing device 602 may be a complex instruction set computing (CISC) microprocessor, a reduced instruction set computing (RISC) microprocessor, a very long instruction word (VLIW) microprocessor, a processor implementing other instruction sets, or other processors implementing a combination of instruction sets. The processing device 602 is configured to execute processing logic in instructions for performing the operations and steps discussed herein.

The computer system 600 may further include a network interface device 610. The computer system 600 also may or may not include an input 612, configured to receive input and selections to be communicated to the computer system 600 when executing instructions. The computer system 600 also may or may not include an output 614, including but not limited to a display, a video display unit (e.g., a liquid crystal display (LCD) or a cathode ray tube (CRT)), an alphanumeric input device (e.g., a keyboard), and/or a cursor control device (e.g., a mouse).

The computer system 600 may or may not include a data storage device that includes instructions 616 stored in a computer readable medium 618. The instructions 616 may also reside, completely or at least partially, within the main memory 604 and/or within the processing device 602 during execution thereof by the computer system 600, with the main memory 604 and the processing device 602 also constituting computer readable medium. The instructions 616 may further be transmitted or received over a network 620 via the network interface device 610.

While the computer readable medium 618 is shown in FIG. 6 to be a single medium, the term “computer readable medium” should be taken to include a single medium or multiple media (e.g., a centralized or distributed database, and/or associated caches and servers) that store the one or more sets of instructions 616. The term “computer readable medium” shall also be taken to include any medium that is capable of storing, encoding, or carrying a set of instructions for execution by the processing device and that causes the processing device to perform any one or more of the methodologies of the embodiments disclosed herein. The term “computer readable medium” shall accordingly be taken to include, but not be limited to, solid-state memories, optical medium, and magnetic medium.

The embodiments disclosed herein include various steps. The steps of the embodiments disclosed herein may be formed by hardware components or may be embodied in machine-executable instructions, which may be used to cause a general-purpose or special-purpose processor programmed with the instructions to perform the steps. Alternatively, the steps may be performed by a combination of hardware and software.

The embodiments disclosed herein may be provided as a computer program product, or software, that may include a machine-readable medium (or computer readable medium) having stored thereon instructions which may be used to program a computer system (or other electronic devices) to perform a process according to the embodiments disclosed herein. A machine-readable medium includes any mechanism for storing or transmitting information in a form readable by a machine (e.g., a computer). For example, a machine-readable medium includes: a machine-readable storage medium (e.g., ROM, random access memory (“RAM”), a magnetic disk storage medium, an optical storage medium, flash memory devices, etc.); and the like.

Unless specifically stated otherwise and as apparent from the previous discussion, it is appreciated that throughout the description, discussions utilizing terms such as “processing,” “computing,” “determining,” “displaying,” or the like, refer to the action and processes of a computer system, or a similar electronic computing device, that manipulates and transforms data and memories represented as physical (electronic) quantities within the computer system's registers into other data similarly represented as physical quantities within the computer system memories or registers or other such information storage, transmission, or display devices.

The algorithms and displays presented herein are not inherently related to any particular computer or other apparatus. Various systems may be used with programs in accordance with the teachings herein, or it may prove convenient to construct more specialized apparatuses to perform the required method steps. The required structure for a variety of these systems is disclosed in the description above. In addition, the embodiments described herein are not described with reference to any particular programming language. It will be appreciated that a variety of programming languages may be used to implement the teachings of the embodiments as described herein.

Those of skill in the art will further appreciate that the various illustrative logical blocks, modules, circuits, and algorithms described in connection with the embodiments disclosed herein may be implemented or performed with a processor, a Digital Signal Processor (DSP), an Application Specific Integrated Circuit (ASIC), a Field Programmable Gate Array (FPGA), a graphics processing unit (GPU) or other programmable logic device, a discrete gate or transistor logic, discrete hardware components, or any combination thereof designed to perform the functions described herein. The components of the distributed AFI tracking system described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends on the particular application, design choices, and/or design constraints imposed on the overall system. Skilled artisans may implement the described functionality in varying ways for each particular application, but such implementation decisions should not be interpreted as causing a departure from the scope of the present embodiments.

The various illustrative logical blocks, modules, and circuits described in connection with the embodiments disclosed herein may be implemented or performed with a processor, a Digital Signal Processor (DSP), an Application Specific Integrated Circuit (ASIC), a Field Programmable Gate Array (FPGA), a Graphics Processing Unit (GPU) or other programmable logic device, a discrete gate or transistor logic, discrete hardware components, or any combination thereof designed to perform the functions described herein. Furthermore, a controller may be a processor. A processor may be a microprocessor, but in the alternative, the processor may be any conventional processor, controller, microcontroller, or state machine. A processor may also be implemented as a combination of computing devices (e.g., a DSP and a microprocessor, a plurality of microprocessors, one or more microprocessors in conjunction with a DSP core, or any other such configuration).

The embodiments disclosed herein may be embodied in hardware and in instructions that are stored in hardware, and may reside, for example, in RAM, flash memory, ROM, Electrically Programmable ROM (EPROM), Electrically Erasable Programmable ROM (EEPROM), registers, a hard disk, a removable disk, a CD-ROM, or any other form of computer readable medium known in the art. A storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the embodiments herein are described to provide examples and discussion. The operations described may be performed in numerous different sequences other than the illustrated sequences. Furthermore, operations described in a single operational step may actually be performed in a number of different steps. Additionally, one or more operational steps discussed in the embodiments may be combined. Those of skill in the art will also understand that information and signals may be represented using any of a variety of technologies and techniques. For example, data, instructions, commands, information, signals, bits, symbols, and chips, which may be referenced throughout the above description, may be represented by voltages, currents, electromagnetic waves, magnetic fields, particles, optical fields, or any combination thereof.

Unless otherwise expressly stated, it is in no way intended that any method set forth herein be construed as requiring that its steps be performed in a specific order. Accordingly, where a method claim does not actually recite an order to be followed by its steps, or it is not otherwise specifically stated in the claims or descriptions that the steps are to be limited to a specific order, it is in no way intended that any particular order be inferred.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A method of extracting non-linear compact model parameters for semiconductor devices using a convolutional neural network (CNN), the method comprising:
receiving input data that is sample points representing electrical characteristics of a semiconductor device;
processing the input data through one or more convolution layers of the CNN to detect local patterns and extract features, creating processed data and extracted features;
down-sampling the processed data through one or more pooling layers of the CNN to reduce spatial dimensions while retaining important features;
passing an output of the one or more pooling layers through one or more fully connected layers of the CNN to perform high-level reasoning and decision-making based on the extracted features; and
generating predictions for parameters of a non-linear compact model using an output layer of the CNN.

2. The method of claim 1 wherein the local patterns detected by the one or more convolution layers are not image features but are instead electrical characteristics of electronic devices.

3. The method of claim 1 further comprising reshaping input voltage data to generate a shaped data set with array dimensions based on a number of input voltage steps generated for the semiconductor device.

4. The method of claim 3 further comprising scaling the shaped data set according to a range of values in the semiconductor device's measured current or other relevant measured electrical quantities.

5. The method of claim 1 wherein the CNN includes at least two convolutional kernels with a same padding and a maximum pooling layer.

6. The method of claim 1 further comprising using a maximum pooling layer in the CNN to reduce variations in the input data that may include out-of-range values and thereby reduce predicting out-of-range values for each parameter.

7. The method of claim 1 wherein the non-linear compact model is an Advanced Simulation Program with Integrated Circuit Emphasis (SPICE) Model for high electron mobility transistors (ASM-HEMT) non-linear compact model, and wherein the parameters extracted by the CNN include at least one of: VOFF, VDSCALE, ETA0, NFACTOR, CDSCD, LAMBDA, U0, MEXPACCD, MEXPACCS, NS0ACCD, NS0ACCS, U0ACCD, U0ACCS, VSATACCS, and VSAT.

8. The method of claim 1 wherein the CNN includes one or more residual blocks comprising:
an activation function; and
a skip connection that adds the input to the output of the one or more convolution layers.

9. The method of claim 1 wherein the CNN further comprises at least one attention layer configured to:
compute attention weights for the extracted features from the one or more convolution layers; and
generate an attentive representation by weighting the extracted features according to the computed attention weights.

10. The method of claim 1 wherein the CNN comprises both residual blocks and at least one attention layer, wherein:
the residual blocks are configured to preserve important features across multiple layers; and
the at least one attention layer is configured to focus on more relevant features within the input data.

11. A convolutional neural network (CNN) for extracting non-linear compact model parameters for semiconductor devices, the CNN comprising:
an input layer configured to receive input data that is sample points representing electrical characteristics of a semiconductor device;
one or more convolution layers configured to process the input data, creating processed data, and detect local patterns and extract features, creating extracted features, wherein the local patterns detected by the convolution layers are not image features but are instead electrical characteristics of electronic devices;
one or more pooling layers down-sampling the processed data to reduce spatial dimensions while retaining important features;
one or more fully connected layers configured to perform high-level reasoning and decision-making based on the extracted features; and
an output layer configured to generate predictions for parameters of a non-linear compact model.

12. The CNN of claim 11 further comprising a maximum pooling layer used to reduce variations in the input data that may include out-of-range values and thereby reduce the possibility of predicting out-of-range values for each parameter.

13. The CNN of claim 11 wherein the non-linear compact model is an Advanced SPICE Model for high electron mobility transistors (ASM-HEMT) non-linear compact model, and wherein the parameters extracted by the CNN include at least one of: VOFF, VDSCALE, ETA0, NFACTOR, CDSCD, LAMBDA, U0, MEXPACCD, MEXPACCS, NS0ACCD, NS0ACCS, U0ACCD, U0ACCS, VSATACCS, and VSAT.

14. The CNN of claim 11 wherein the CNN includes one or more residual blocks comprising:
an activation function; and
a skip connection that adds the input to the output of the one or more convolution layers.

15. The CNN of claim 11 wherein the CNN further comprises at least one attention layer configured to:
compute attention weights for the extracted features from the one or more convolution layers; and
generate an attentive representation by weighting the extracted features according to the computed attention weights.

16. The CNN of claim 11 wherein the CNN comprises both residual blocks and at least one attention layer, wherein:
the residual blocks are configured to preserve important features across multiple layers;
the at least one attention layer is configured to focus on more relevant features within the input data.

17. A system for extracting non-linear compact model parameters for semiconductor devices, the system comprising:
a memory configured to store input data that is sample points representing electrical characteristics of a semiconductor device; and
a processor configured to execute instructions stored in the memory, the instructions comprising:
processing the input data through one or more convolution layers of a CNN, creating processed data, to detect local patterns and extract features, creating extracted features, wherein the local patterns detected by the convolution layers are not image features but are instead electrical characteristics of electronic devices;
down-sampling the processed data through one or more pooling layers of the CNN to reduce spatial dimensions while retaining important features;
passing an output of the pooling layers through one or more fully connected layers of the CNN to perform high-level reasoning and decision-making based on the extracted features; and
generating predictions for parameters of a non-linear compact model using an output layer of the CNN.

18. The system of claim 17 further comprising a maximum pooling layer used to enforce physical ranges for semiconductor device parameters to be predicted by limiting a maximum value that can be predicted for each parameter.

19. The system of claim 17 wherein the non-linear compact model is an Advanced SPICE Model for high electron mobility transistors (ASM-HEMT) non-linear compact model, and wherein the parameters extracted by the CNN include at least one of: VOFF, VDSCALE, ETA0, NFACTOR, CDSCD, LAMBDA, U0, MEXPACCD, MEXPACCS, NS0ACCD, NS0ACCS, U0ACCD, U0ACCS, VSATACCS, and VSAT.

20. The system of claim 17 wherein the CNN includes one or more residual blocks comprising:
an activation function; and
a skip connection that adds the input to the output of the one or more convolution layers.

21. The system of claim 17 wherein the CNN further comprises at least one attention layer configured to:
compute attention weights for the extracted features from the one or more convolution layers; and
generate an attentive representation by weighting the extracted features according to the computed attention weights.

22. The system of claim 17 wherein the CNN comprises both residual blocks and at least one attention layer, wherein:
the residual blocks are configured to preserve important features across multiple layers;
the at least one attention layer is configured to focus on more relevant features within the input data.

23. A non-transitory computer-readable medium storing instructions that, when executed by a processor, perform a method of extracting non-linear compact model parameters for semiconductor devices using a convolutional neural network (CNN), the method comprising:
receiving input data representing electrical characteristics of a semiconductor device;
processing the input data through one or more convolution layers of the CNN, creating processed data, to detect local patterns and extract features, creating extracted features, wherein the local patterns detected by the one or more convolution layers are not image features but are instead electrical characteristics of electronic devices;
down-sampling the processed data through one or more pooling layers of the CNN to reduce spatial dimensions while retaining important features;
passing an output of the pooling layers through one or more fully connected layers of the CNN to perform high-level reasoning and decision-making based on the extracted features; and
generating predictions for parameters of a non-linear compact model using an output layer of the CNN.

24. The non-transitory computer-readable medium of claim 23 wherein the method further comprises reshaping input voltage data to generate a shaped data set with array dimensions based on a number of input voltage steps generated for the semiconductor device.

25. The non-transitory computer-readable medium of claim 24 wherein the method further comprises scaling the shaped data set according to a range of values in the semiconductor device's measured current or other relevant measured electrical quantities.

26. The non-transitory computer-readable medium of claim 23 wherein the CNN comprises at least two convolutional kernels with a same padding and a maximum pooling layer.

27. The non-transitory computer-readable medium of claim 23 wherein the method further comprises using a maximum pooling layer in the CNN to reduce variations in the input data that may include out-of-range values and thereby reduce the possibility of predicting out-of-range values for each parameter.

28. The non-transitory computer-readable medium of claim 23 wherein the non-linear compact model is an Advanced SPICE Model for high electron mobility transistors (ASM-HEMT) non-linear compact model, and wherein the parameters extracted by the CNN include at least one of: VOFF, VDSCALE, ETA0, NFACTOR, CDSCD, LAMBDA, U0, MEXPACCD, MEXPACCS, NS0ACCD, NS0ACCS, U0ACCD, U0ACCS, VSATACCS, and VSAT.

29. The non-transitory computer-readable medium of claim 23 wherein the instructions are stored in one or more of the following types of memory: random access memory (RAM), flash memory, read only memory (ROM), Electrically Programmable ROM (EPROM), Electrically Erasable Programmable ROM (EEPROM), registers, a hard disk, a removable disk, or a CD-ROM.

30. The non-transitory computer-readable medium of claim 23 wherein the CNN architecture includes one or more residual blocks comprising:
an activation function; and
a skip connection that adds the input to the output of the one or more convolution layers.

31. The non-transitory computer-readable medium of claim 23 wherein the CNN architecture wherein the CNN further comprises at least one attention layer configured to:
compute attention weights for the extracted features from the one or more convolution layers; and
generate an attentive representation by weighting the extracted features according to the computed attention weights.

32. The non-transitory computer-readable medium of claim 23 wherein the CNN comprises both residual blocks and at least one attention layer, wherein:
the residual blocks are configured to preserve important features across multiple layers; and
the at least one attention layer is configured to focus on more relevant features within the input data.
